(19) United States
(12) Patent Application Publication
(10) Pub. No.: US 2025/0392265 A1
(43) Pub. Date: Dec. 25, 2025

(54) Cylindrical Coaxial Combiner

(71) Applicant: THALES, MEUDON (FR)

(72) Inventors: Théo SPILLEBOUT, VELIZY (FR); Florian GESLIN, VELIZY (FR); Alberto LEGGIERI, BIEVRES (FR); Bertrand GERFAULT, JOUY EN JOSAS (FR)

(21) Appl. No.: 18/636,207

(22) Filed: Apr. 15, 2024

(30) Foreign Application Priority Data
Apr. 28, 2023 (FR) 2304321

(51) Int. Cl. H03F 1/30; H01P 5/12

(52) U.S. Cl. CPC H03F 1/30; H01P 5/12

(57) ABSTRACT

A cylindrical coaxial combiner includes an inner conductor of rectangular section; an outer cover of rectangular section; a cavity between the inner conductor and the outer cover; two outer conductors disposed at the ends of the outer cover, provided with a coaxial connector at their outer end; power amplifying electronic circuit boards connected electrically to the inner conductor; at least one solid-state amplifier, per power amplifying electronic circuit board; and a cooling circuit comprising at least one through portion configured to make a heat-transfer fluid circulate, to inside the inner conductor of the coaxial combiner, disposed in contact with the rear part of a power amplifying electronic circuit board on which at least one solid-state amplifier is disposed.

### CROSS-REFERENCE TO RELATED APPLICATION

This application claims priority to foreign French patent application No. FR 2304321, filed on April 28, 2023, the disclosure of which is incorporated by reference in its entirety.

### FIELD OF THE INVENTION

The invention relates to a cylindrical coaxial combiner.

The present invention relates to the field of the amplification of power from solid-state amplifiers, or SSPA, the abbreviation for “Solid-state Power Amplifier”, and more specifically the combination of power, for any type of applications, whether they be military (countermeasure, scrambling, radar, transmission) or civilian (industrial, commercial or scientific).

### BACKGROUND

In order for power electronic tubes to be able to compete, it is necessary to combine several of them together. In this field, the wider the bandwidth, the greater the power to be dissipated. In addition, the power sources dissipate the power on a very small surface, which makes power densities to be dissipated of the order of a hundred or so kW.m⁻².

The present invention falls within the scope of an approach aiming to develop a solid-state amplifier solution that makes it possible to rival the current microwave tube amplifiers, or TWTA, the acronym for “Travelling Wave Tube Amplifiers”, which these days have no equivalent in terms of compactness and power density, but also other types of solid-state amplifier with conventional or spatial combination.

One important aspect is the minimising of the temperature rise between the cold source available and the hot source, i.e. the solid-state amplifier, which depends linearly on the distance between the two elements. Thus, to manage such power densities, it is essential to minimise the distance between the hot source and the cold source.

Many of the applications targeted, like aviation or aerospace, take place in confined media with a volume to be occupied which is limited. This is why it is important for the devices to occupy the least possible space.

The main known devices make use of particularly powerful elements, such as heat pipes, to establish the join between the hot source and the cold source. However, these elements, however powerful they may be, remain lesser than a direct connection between the two sources.

The recent advances made in the field of transistors in GaN (Gallium Nitride) technology make it possible to envisage achieving such power density levels in a range ranging from a hundred or so watts to a kilowatt continuously (CW, the acronym for “Continuous Wave”).

The choice of the combination solution is then a determining criterion in a quest for power and bandwidth, while being the most compact possible, which presents a certain difficulty when wanting to cover bands ranging from 2 to 18 GHz with power levels greater than 100W CW.

The solid-state amplifiers or high-power SSPA exhibit very high power densities, of the order of 50 MW/m². Furthermore, when the solid-state amplifiers are wideband, their power added efficiency (ratio between the power gain and the total power consumed), or PAE, is low, i.e. <25%, which increases the need for thermal dissipation with constant output power. This type of very strong power density application has low efficiency, which is the most difficult to manage.

One major aspect of the heat dissipation is the distance between the hot source and the cold source and the maximisation of the exchange surface area. Indeed, the greater the distance between the two, the greater the thermal resistance and therefore the higher the temperature rise.

This problem arises particularly in the spatial combination systems which are made to combine a large number of amplifiers at the same time and said significant number of amplifiers means a lot of power to be dissipated.

Also known are Tube Amplifiers of travelling wave tube, or TWT, type, in which a filament is heated up and produces a release of electrons by thermo-ionic emission. These electrons are then accelerated in a vacuum by an electrical field of high intensity generated by a very high voltage, with the acronym VHV. Once accelerated, these electrons are focused in a beam which interacts with a microfrequency wave. Gradually, the direct current energy, of acronym DC, contained in the electron beam is converted little-by-little into microfrequency energy as the electrons travel the line of interaction. This energy is then transmitted out of the tube while the residual energy is transmitted to the collector and will be dissipated in heat form.

The travelling wave tubes have the advantage of having a great compactness and high-efficiency, but, on the other hand, they operate in all-or-nothing mode, i.e, in the event of a failure, the product is out of use, necessitates a very high voltage VHV, requires high technicality, is very costly to produce, and very difficult to keep operational.

As described in the document US 10818998 B2, solid-state amplifiers SSPA in spatial combination are known, comprising monolithic modules combined through antipodal lines of Vivaldi type which then radiate in cavities which constitute the input points of a conical cavity combiner.

Such amplifiers make it possible to have a good compactness, fairly low losses, and an absence of interconnection problems between stages. On the other hand, they have a radial combination which makes the thermal management very complex, are complex to maintain and it is almost impossible for them to operate optimally in pulsed mode because the energy reservoir capacitances cannot be placed as close as possible to the monolithic modules.

The document US 11255608 B2 presents a liquid cooling system which surrounds the combination structure with a conductor between the amplifiers and the cold fluid circulation network. To this cooling circuit on the outer layer can be added an inner system using the central cylinder on which all of the elements bear and which could also accommodate a circulation of cold fluid.

The document US 10539371 B2 presents a system similar to the preceding one. The difference is in the form and the integration of the cooling circuit. This device is a kind of coil incorporated in the structure gripping the combination device while the preceding one was located between the combination architecture and this final outer structure gripping all of the other elements.

These latter two types of cooling systems set out to describe the possibilities of fluid circulation around the amplification structure.

Also known is the document US 2022/0279676 A1, which presents the possibilities of conduction between the amplifier and the cooling system which could correspond to the two types of cooling cited above. This document sets out to describe the potentials of integration of very conventional heat sinks like a copper-based heat sink or more sophisticated heat pipe-based heat sinks.

None of these existing solutions is therefore satisfactory because all present major defects.

Also known is the document "THE SQUARAX SPATIAL POWER COMBINER" from Progress In Electromagnetics Research C, Vol. 45, 43-55, from the Dipartimento di Ingegneria Elettronica, Universitµa degli Studi di Roma, dated 2013, which does not resolve the technical and technological production problems, notably the issue of thermal management which is often pointed to as being the weakness of the spatial combiners.

Fig.1 schematically illustrates such a cylindrical coaxial combiner, named squarax. The squarax is a coaxial combiner which comprises an inner conductor 1 of rectangular section, an outer cover 2 of rectangular section, and two outer conductors 3 disposed at the ends of the outer cover 2. Each of the outer conductors 3 is provided with a coaxial connector 4 at their outer end. It also comprises power amplifying electronic circuit boards 5, in this case eight power amplifying electronic circuit boards 5, provided with solid-state amplifiers or SSPA 6.

In Fig.1, and in all the other figures of the state of the art or of the invention, the Fin Lin transitions or particular quasi-planar transmission line, are not represented.

Fig.2 schematically illustrates a cross-sectional view of the squarax, transversal to its longitudinal axis.

Fig.3 schematically illustrates a front view of a power amplifying electronic circuit board of the squarax cylindrical coaxial combiner.

### SUMMARY OF THE INVENTION

One aim of the invention is to mitigate the problems cited previously.

According to one aspect of the invention, a cylindrical coaxial combiner is proposed comprising: an inner conductor of rectangular section; an outer cover of rectangular section; a cavity between the inner conductor and the outer cover, or, in other words, a space for propagation of the RF waves; two outer conductors disposed at the ends of the outer cover, provided with a coaxial connector at their outer end; power amplifying electronic circuit boards connected electrically to the inner conductor; at least one solid-state amplifier, per power amplifying electronic circuit board, disposed on the board so as to be closer to the outer edge of the board than the inner edge of the board in contact with the inner conductor; and a cooling circuit comprising at least one portion configured to make a heat-transfer fluid circulate, passing through the cavity of the coaxial combiner, the inner conductor, then the cavity of the coaxial combiner, disposed in contact with the rear part of a power amplifying electronic circuit board on which at least one solid-state amplifier is disposed.

In one embodiment, a power amplifying electronic circuit board comprises a central part of a height greater than the rest of the board.

According to one embodiment, the combiner comprises removable elements forming the outer cover facing the central parts of the power amplifying electronic circuit boards.

In one embodiment, the central part of a power amplifying electronic circuit board comprises a cutout in the form of the solid-state amplifier into which the amplifier is inserted through the board.

According to one embodiment, a through portion of the cooling circuit is of oblong section of a length substantially equal to the width of a solid-state amplifier.

According to one embodiment, a through portion of the cooling circuit comprises two orthogonal rectilinear parts linked by a bent part, a rectilinear part being disposed between two solid-state amplifiers.

According to one embodiment, the cooling circuit comprises two through portions that are symmetrical in a cutting plane transversal to the longitudinal axis of the combiner, with respect to an axis passing through two opposite corners of the rectangular cross-section of the inner conductor, each through portion having two orthogonal rectilinear parts linked by a bent part, and each rectilinear part being disposed between two solid-state amplifiers.

In one embodiment, the cooling circuit comprises four through portions pairwise symmetrical in a cutting plane transversal to the longitudinal axis of the combiner, with respect to two mutually right-angled axes, each passing through two media on opposite sides of the rectangular cross-section of the inner conductor, each through portion having two orthogonal rectilinear parts linked by a bent part, and each rectilinear part being disposed between two solid-state amplifiers.

According to one embodiment, the cooling circuit comprises eight through portions that are symmetrical in fours in a cutting plane transversal to the longitudinal axis of the combiner, with respect to two mutually right-angled axes, each passing through two media on opposite sides of the rectangular cross-section of the inner conductor, each through portion having two orthogonal rectilinear parts linked by a bent part, and each rectilinear part being disposed between two solid-state amplifiers.

### BRIEF DESCRIPTION OF THE DRAWINGS

The invention will be better understood on studying a few embodiments described as nonlimiting examples and illustrated by the attached drawings in which:

Fig.1 schematically illustrates a squarax cylindrical coaxial combiner design, according to the state of the art;

Fig.2 schematically illustrates a transverse cross-sectional view of the squarax cylindrical coaxial combiner of Fig.1, according to the state of the art;

Fig.3 schematically illustrates a front view of a power amplifying electronic circuit board of the squarax cylindrical coaxial combiner of Fig.1, according to the state of the art;

Fig.4 schematically illustrates a squarax cylindrical coaxial combiner, in its outer housing, according to one aspect of the invention;

Fig.5 schematically illustrates the squarax cylindrical coaxial combiner of Fig.4, with its outer housing, according to one aspect of the invention;

Fig.6 schematically illustrates a transverse cross-sectional view of the squarax cylindrical coaxial combiner of Fig.4, according to one aspect of the invention;

Fig.7 schematically illustrates a front view of a power amplifying electronic circuit board of the squarax cylindrical coaxial combiner of Fig.4, according to one aspect of the invention;

Fig.8 schematically illustrates a profile view of the power amplifying electronic circuit board of Fig.7, and of a part of the cooling circuit, according to one aspect of the invention;

Fig.9 schematically illustrates an embodiment of a squarax cylindrical coaxial combiner comprising two through portions, according to one aspect of the invention;

Fig.10 schematically illustrates an embodiment of a squarax cylindrical coaxial combiner comprising four through portions, according to one aspect of the invention;

Fig.11 schematically illustrates an embodiment of a squarax cylindrical coaxial combiner comprising eight through portions, according to one aspect of the invention;

Fig.12 schematically illustrates a perspective 3D view of a squarax cylindrical coaxial combiner, according to one aspect of the invention; and

Fig.13 schematically illustrates two solid-state amplifiers or SSPA.

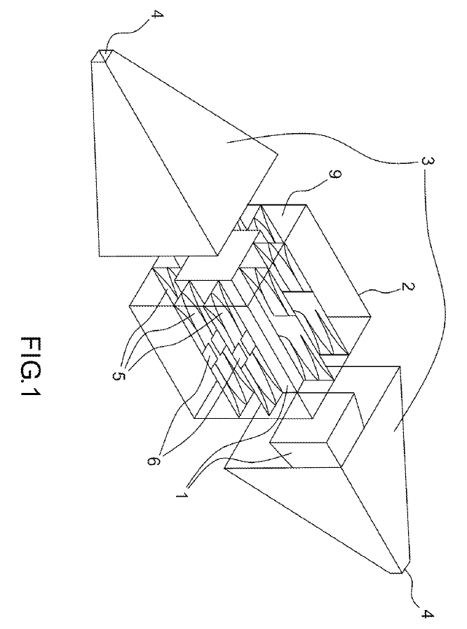

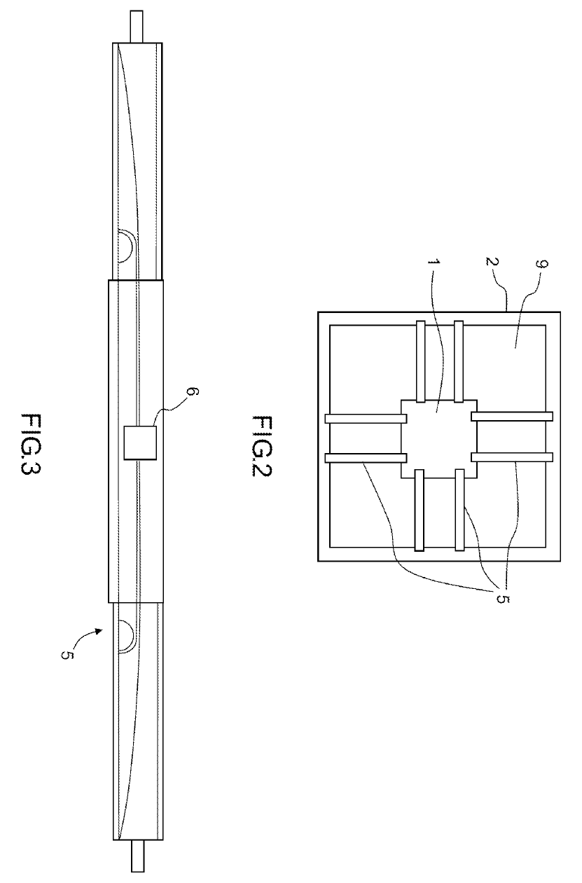

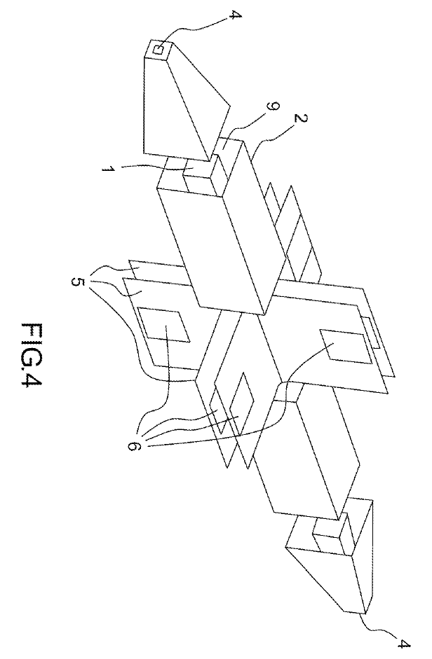

In all the figures, the elements that have identical references are similar.

### DETAILED DESCRIPTION

Fig.4 schematically illustrates a squarax cylindrical coaxial combiner, in its outer housing, according to one aspect of the invention. The squarax cylindrical coaxial combiner comprises an inner conductor 1 of rectangular section, an outer cover 2 of rectangular section, and two outer conductors 3 disposed at the ends of the outer cover, provided with a coaxial connector 4 at their outer end. For example, the outer conductors 3 are provided at their outer end with a port of SMA, the acronym for “SubMiniature version A”, type. It also comprises power amplifying electronic circuit boards 5, in this case eight power amplifying electronic circuit boards 5.

The squarax cylindrical coaxial combiner comprises at least one solid-state amplifier 6, or SSPA, per power amplifying electronic circuit board 5, disposed on the board 5 so as to be closer to the outer edge of the board 5 than the inner edge of the board in contact with the inner conductor 1.

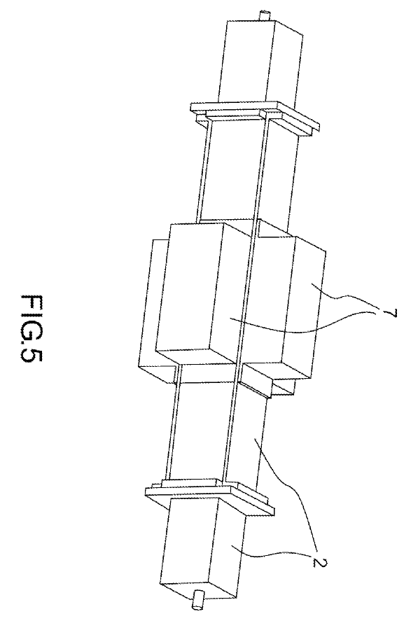

The squarax cylindrical coaxial combiner further comprises a cooling circuit, not represented in Fig.4, or in Fig.5, representing an example of production of the outer cover 2 of rectangular section, which also comprises removable elements 7 forming the outer cover facing the central parts of the power amplifying electronic circuit boards 5.

This part comprising removable elements 7 allows easy access for repairing or replacing elements of the squarax cylindrical coaxial combiner.

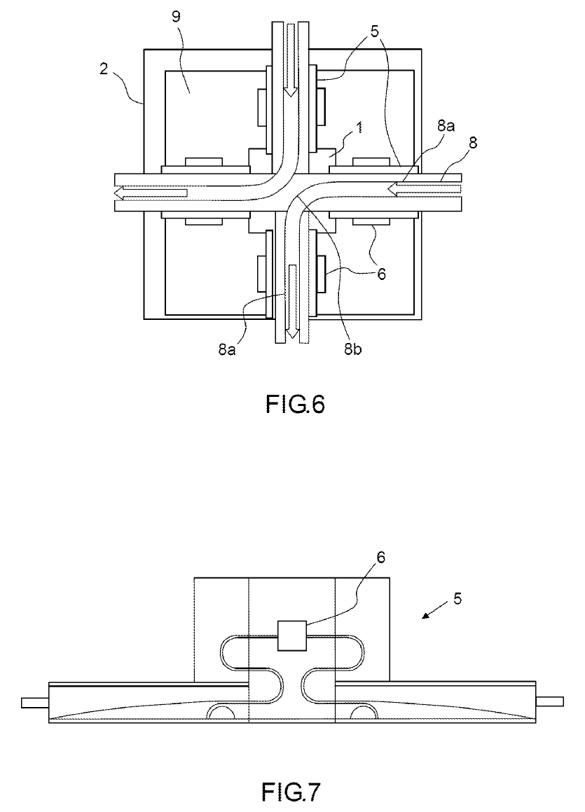

Fig.6 schematically illustrates a transverse cross-sectional view of the squarax cylindrical coaxial combiner of Fig.4, on which a part of the cooling circuit is represented. The cooling circuit comprises at least one through portion 8 configured to make a heat-transfer fluid circulate, passing through the cavity 9 of the coaxial combiner, the inner conductor 1, then the cavity 9 of the coaxial combiner, disposed in contact with the rear part of a power amplifying electronic circuit board 5 on which at least one solid-state amplifier 6 is disposed.

An example of circulation of heat-transfer fluid in the cooling circuit, or more particularly in the through portions 8, is represented by arrows.

Fig.7 illustrates an electronic circuit board, the central part of which has a height greater than the rest of the board, which makes it possible to accommodate all of the elements necessary to the operation of the amplifiers while increasing the space left for the cooling system.

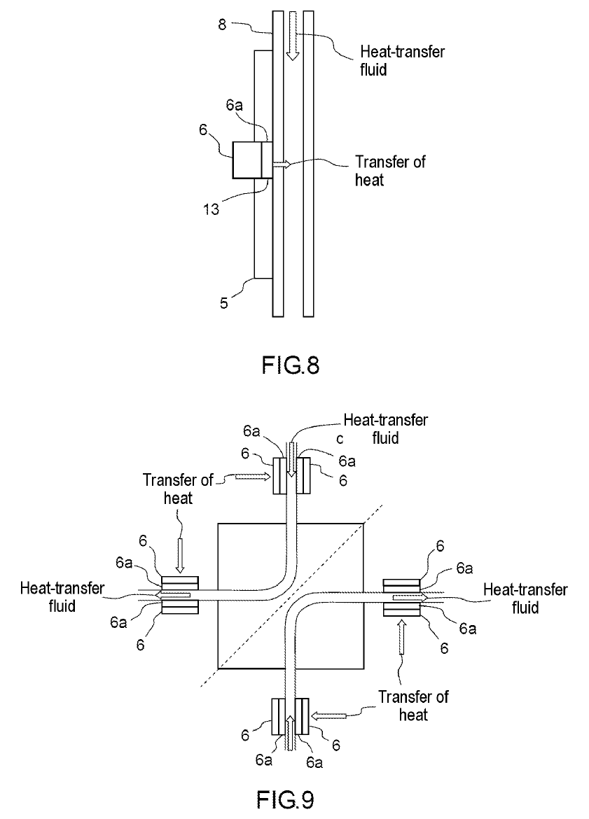

As illustrated in Fig.8 the combiner makes it possible to make the heat-transfer fluid of the cooling circuit circulate directly under the heat sink 6a of an SSPA 6.

In the devices of the state of the art, the heat sink described served only as thermal conductor. In addition, its useful exchange surface was not optimal since the heat exchange was not done on the largest of its faces and did not therefore give the best exchange conditions. In the state of the art, the heat sink of the circular combiners is a pie segment while, for the rectangular combiner, it is a straight block. This change is linked to the particular geometry of each of these combiners. These heat sinks have two roles, to conduct and to dissipate. Conduction represents the routing of the calories to the exchange surface with the cold source which is the only one to be dissipated specifically speaking. It is essential for the conduction path to be as short as possible and the exchange surface to be as large as possible. By considering that the materials have a perfect thermal conductivity, it is possible to perfectly compensate a lesser dissipation by a larger exchange surface, but that is done to the detriment of compactness. Clearly our device guarantees a shorter path by at least one order of magnitude (transition from cm to mm), and thus allows for increased compactness. It can be estimated that, with a conventional finned system, the volume would be doubled.

In the present invention, the heat sink 6a of an SSPA 6 and the heat-transfer fluid circulating in a through portion 8 of the cooling circuit are one. The thermal advantage is in maximising the exchange surface while minimising the thermal distance between the hot source (the SSPA 6) and the cold source (the heat-transfer fluid). The advantage in terms of compactness is that the same device fulfils two functions, establishing a thermal bridge and making the heat-transfer fluid circulate.

As illustrated in Fig.8, the central part of a power amplifying electronic circuit board 5 comprises a cutout in the form of the solid-state amplifier or SSPA 6, into which is inserted an amplifier passing through the board 5.

In the combiners of the state of the art, the SSPAs are fixed directly onto the power amplifying electronic circuit board, so there are two barriers between the cooling element and the hot source: the heat sink of the SSPA and the ceramic substrate of the power amplifying electronic circuit board.

Also, the cutout according to the invention of the electronic circuit board 5, so as to be able to insert the SSPA 6 therein, all fixed directly against a through portion 8 of the cooling circuit, makes it possible to remove one thermal barrier, which significantly increases the heat dissipation capabilities of the system. Furthermore, that minimises the heat flux absorbed by the electronic circuit board 5 and therefore minimises the thermal expansion of the substrate of the electronic circuit board 5, a source of deformations and therefore of degradation of the performance levels, even of mechanical breakage. This constraint is often limiting in the choice of the substrate of the power amplifying electronic circuit board 5.

Furthermore, the squarax cylindrical coaxial combiner according to one aspect of the invention makes it possible to make the heat-transfer fluid circulate just behind the substrate of the power amplifying electronic circuit boards 5, which is impossible in the context of the cylindrical coaxial structures of the state of the art.

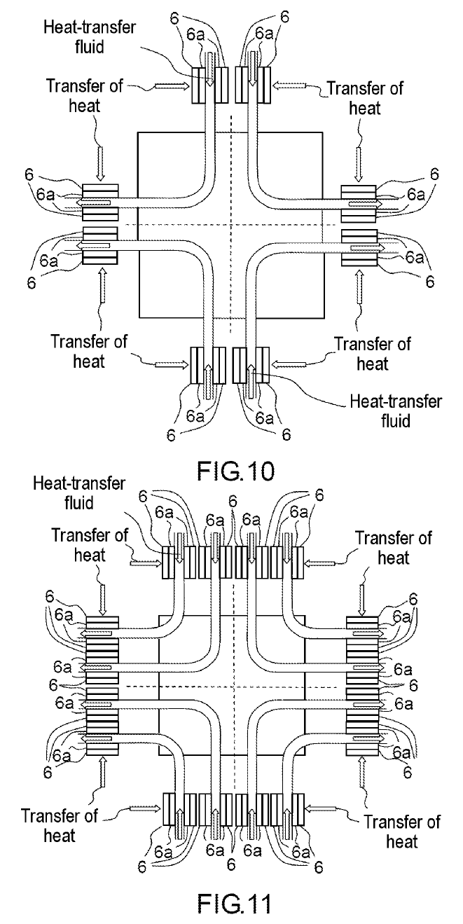

According to embodiments of the invention, such a squarax cylindrical coaxial combiner can offer design advantages, as illustrated in the embodiments of Fig.9, Fig.10 and Fig.11.

In the embodiment of Fig.9, the cooling circuit comprises two through portions 8 that are symmetrical in a cutting plane transversal to the longitudinal axis of the combiner, with respect to an axis 11 passing through two opposite corners of the rectangular cross-section of the inner conductor 1, each through portion having two orthogonal rectilinear parts 8a linked by a bent part 8b, and each rectilinear part 8a being disposed between two solid-state amplifiers or SSPA 6.

In the embodiment of Fig.10, the cooling circuit comprises four through portions 8 that are pairwise symmetrical in a cutting plane transversal to the longitudinal axis of the combiner, with respect to two mutually right-angled axes 12, 13, each passing through two media on opposite sides of the rectangular cross-section of the inner conductor 1, each through portion 8 having two orthogonal rectilinear parts 8a linked by a bent part 8b, and each rectilinear part 8a being disposed between two solid-state amplifiers 6.

In the embodiment of Fig.11, the cooling circuit comprises eight through portions 8 arranged in fours that are symmetrical in a cutting plane transversal to the longitudinal axis of the combiner, with respect to two mutually right-angled axes 12, 13, each passing through two media on opposite sides of the rectangular cross-section of the inner conductor 1, each through portion having two orthogonal rectilinear parts 8a linked by a bent part 8b, and each rectilinear part 8a being disposed between two solid-state amplifiers 6.

In these three embodiments, symmetries are clearly apparent, making it possible to produce sets of parts that are identical to produce, then to assemble. That makes it possible to minimise the number of parts to be produced and therefore the associated costs. The parts linked to the thermal cooling form an integral part of the structure, they are not distinct. Thus, no consideration is therefore given to the possible differential expansions between distinct materials. They can be assembled together by simple screwing to form the final structure.

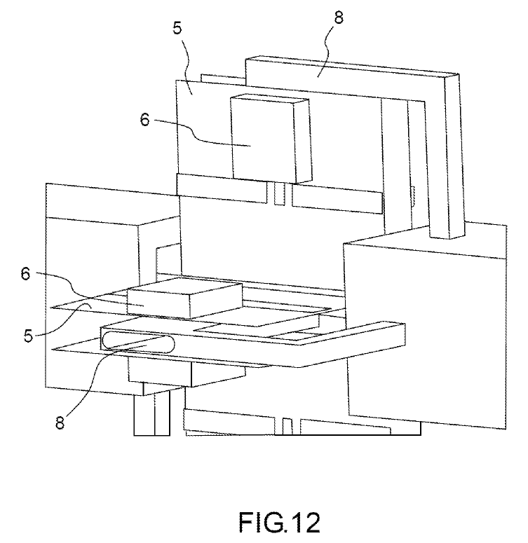

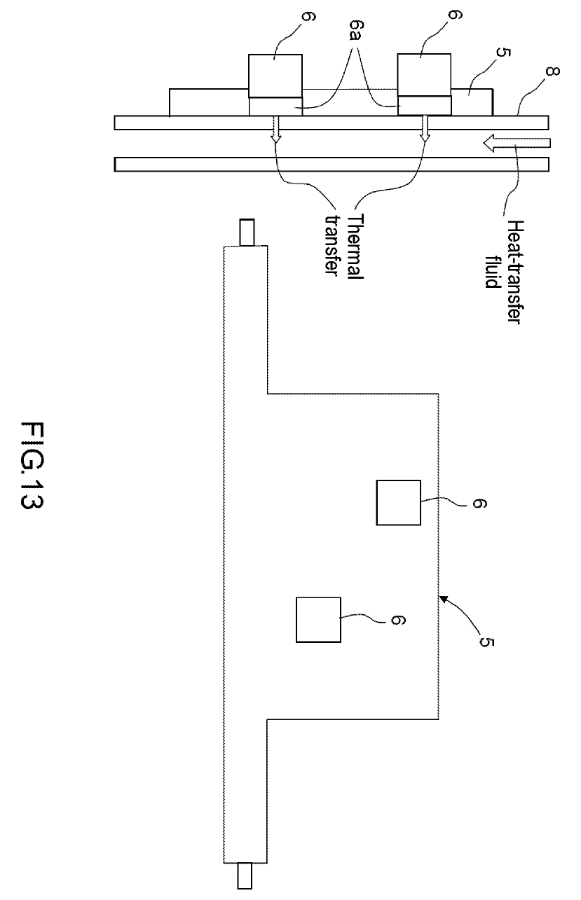

Fig.12 schematically illustrates a perspective 3D view of a squarax cylindrical coaxial combiner, according to one aspect of the invention, and Fig.13 schematically illustrates two solid-state amplifiers or SSPA.

The cylindrical coaxial combiner according to the invention makes it possible to cool directly under the power amplifying electronic circuit boards through the optimal exchange surface of the heat sinks 6a of the SSPAs 6, while minimising the distance between the hot source and the cold source, which commensurately reduces the temperature rise.

Furthermore, a cylindrical coaxial combiner according to the invention making one and the same element fulfil two functions makes it possible to improve the compactness of the device, no new element being added to the structure from the outside. This novel system makes it possible to dissipate power densities up to three times greater than according to the combiners of the state of the art and two times greater than those required by the best current SSPAs.

1. A cylindrical coaxial combiner comprising:
an inner conductor of rectangular section;
an outer cover of rectangular section;
a cavity between the inner conductor and the outer cover;
two outer conductors disposed at the ends of the outer cover, provided with a coaxial connector at their outer end;
power amplifying electronic circuit boards connected electrically to the inner conductor;
at least one solid-state amplifier, per power amplifying electronic circuit board, disposed on the board so as to be closer to the outer edge of the board than the inner edge of the board in contact with the inner conductor; and
a cooling circuit comprising at least one through portion configured to make a heat-transfer fluid circulate, passing through the cavity of the coaxial combiner, the inner conductor, then the cavity of the coaxial combiner, disposed in contact with the rear part of a power amplifying electronic circuit board on which at least one solid-state amplifier is disposed.

2. The combiner according to claim 1, wherein a power amplifying electronic circuit board comprises a central part of a height greater than the rest of the board.

3. The combiner according to claim 2, comprising removable elements forming the outer cover facing central parts of the power amplifying electronic circuit boards.

4. The combiner according to claim 1, wherein the central part of a power amplifying electronic circuit board comprises a cutout in the form of the solid-state amplifier into which the amplifier is inserted passing through the board.

5. The combiner according to claim 1, wherein a through portion of the cooling circuit is of oblong section and of a length substantially equal to the width of a solid-state amplifier.

6. The combiner according to claim 1, wherein a through portion of the cooling circuit comprises two orthogonal rectilinear parts linked by a bent part, a rectilinear part being disposed between two solid-state amplifiers.

7. The combiner according to claim 6, wherein the cooling circuit comprises two through portions that are symmetrical in a cutting plane transversal to the longitudinal axis of the combiner, with respect to an axis passing through two opposite corners of the rectangular cross-section of the inner conductor, each through portion having two orthogonal rectilinear parts linked by a bent part, and each rectilinear part being disposed between two solid-state amplifiers.

8. The combiner according to claim 6, wherein the cooling circuit comprises four through portions that are pairwise symmetrical in a cutting plane transversal to the longitudinal axis of the combiner, with respect to two mutually right-angled axes, each passing through two media on opposite sides of the rectangular cross-section of the inner conductor, each through portion having two orthogonal rectilinear parts linked by a bent part, and each rectilinear part being disposed between two solid-state amplifiers.

9. The combiner according to claim 6, wherein the cooling circuit comprises eight through portions arranged in fours that are symmetrical in a cutting plane transversal to the longitudinal axis of the combiner, with respect to two mutually right-angled axes, each passing through two media on opposite sides of the rectangular cross-section of the inner conductor, each through portion having two orthogonal rectilinear parts linked by a bent part, and each rectilinear part being disposed between two solid-state amplifiers.
